(19) United States
(12) Patent Application Publication
(10) Pub. No.: US 2025/0279346 A1
(43) Pub. Date: Sep. 4, 2025

(54) HIGH ASPECT RATIO VIAS WITH LOW STRESS IN INTEGRATED CIRCUIT PACKAGES

(71) Applicant: Intel Corporation, Santa Clara, CA (US)

(72) Inventors: Kihyun Kim, Chandler, AZ (US); Micah David Armstrong, Gilbert, AZ (US); Darko Grujicic, Chandler, AZ (US); Shayan Kaviani, Phoenix, AZ (US); Rahul Nagaraj Manepalli, Chandler, AZ (US); Srinivas Venkata Ramanuja Pietambaram, Chandler, AZ (US); Dilan Seneviratne, Phoenix, AZ (US); Rengarajan Shanmugam, Tempe, AZ (US); Joshua James Stacey, Chandler, AZ (US); Marcel Arlan Wall, Phoenix, AZ (US); Ehsan Zamani, Phoenix, AZ (US)

(21) Appl. No.: 18/593,337

(22) Filed: Mar. 1, 2024

(51) Int. Cl. H01L 23/498; H01L 23/00; H01L 25/065

(52) U.S. Cl. CPC H01L 23/49838; H01L 23/49822; H01L 24/08; H01L 24/16; H01L 25/0655; H01L 2224/08146; H01L 2224/08155; H01L 2224/16146; H01L 2224/16157; H01L 2924/01029; H01L 2924/1431; H01L 2924/1434; H01L 2924/351

(57) ABSTRACT

High aspect ratio vias with low stress in integrated circuit packages are disclosed. A package substrate includes: a core having a via extending therethrough; a first conductive material in the via; a dielectric material at least partially between a wall of the via and the first conductive material; and a second conductive material in the via. The second conductive material is closer to a central region of the via than the first conductive material is to the central region of the via. The first conductive material is different from the second conductive material. The first conductive material is at least partially between the dielectric material and the second conductive material.

### FIELD OF THE DISCLOSURE

This disclosure relates generally to integrated circuit packages and, more particularly, to high aspect ratio vias with low stress in integrated circuit packages.

### BACKGROUND

In many integrated circuit packages, one or more semiconductor dies are mechanically and electrically coupled to an underlying package substrate. In many cases, such package substrates include a package core that provides structural integrity to the package substrate. In recent years, package substrates have been developed using glass cores. By using laser-assisted etching, crack free, high-density vias (e.g., openings or holes) are formed into a glass core and subsequently plated with metal to serve as electrical pathways or interconnects to carry power and/or signals to and/or from a semiconductor die and/or other electrical component(s) on the package substrate.

### BRIEF DESCRIPTION OF THE DRAWINGS

FIG. 1 illustrates an example integrated circuit (IC) package constructed in accordance with teachings disclosed herein.

FIG. 2 is a cross-sectional view of an example implementation of the package substrate of FIG. 1 at a point in the fabrication process in which the buildup regions of FIG. 1 are partially formed.

FIG. 3 is a cross-sectional view of another example implementation of the package substrate of FIG. 1.

FIGS. 4-9 illustrate different stages during an example fabrication process to manufacture the example through-glass vias (TGVs) shown in FIGS. 2 and/or 3.

FIG. 10 is a flowchart representative of an example method to manufacture any one of the example TGVs of FIGS. 2-9.

FIG. 11 is a top view of a wafer including dies that may be included in an IC package constructed in accordance with teachings disclosed herein.

FIG. 12 is a cross-sectional side view of an IC device that may be included in an IC package constructed in accordance with teachings disclosed herein.

FIG. 13 is a cross-sectional side view of an IC device assembly that may include an IC package constructed in accordance with teachings disclosed herein.

FIG. 14 is a block diagram of an example electrical device that may include an IC package constructed in accordance with teachings disclosed herein.

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

### DETAILED DESCRIPTION

Glass cores for package substrates provide mechanical and electrical benefits over organic cores (e.g., epoxy-based prepreg layer with glass cloth). Specifically, a glass core provides greater structural rigidity than a similarly sized organic core. Further, glass cores can enable smaller vias distributed at smaller pitches than is possible with organic cores, thereby enabling higher interconnect densities. However, a challenge with glass cores is the large difference in coefficient of thermal expansion (CTE) of the glass relative to the CTE of the conductive material (e.g., plated copper) used for the interconnects extending through the glass core. As a result, there is risk of introducing stress and possibly causing damage to a glass core from the plastic deformation (e.g., expansion and contraction) of the copper relative to the glass core during the different temperature cycles experienced during the fabrication of an associated integrated circuit package (e.g., high temperatures during reflow operations).

Examples disclosed herein mitigate against the concerns of a CTE mismatch by employing a seed layer stack of multiple different materials between the glass core and the copper subsequently plated thereon. More particularly, in some examples, the different materials in the seed layer stack include at least one of a stress reducing liner, a metal seed layer, and an inserter (any of which may themself contain one or more layers of materials). In some examples, the stress reducing liner is a low modulus material that absorbs some of the stress created by the CTE mismatch between the glass and plated copper. The metal seed layer provides electrical conductivity to enable electroplating of the copper. In some such examples, the inserter serves as a transition between the metal seed layer and the plated copper to facilitate the electroplating process and promote adhesion of the copper to the underlying metal seed layer.

Reducing stress between a glass core and plated vias extending through the glass core becomes particularly challenging as the vias reduce in width or diameter because of a resulting increase in the height to width aspect ratio of the vias. In particular, standard techniques for depositing a seed layer into a via (e.g., using physical vapor deposition (PVD)) are limited to aspect ratios of no more than 5 (e.g., vias 5 times longer (taller) than they are wide). Examples disclosed herein rely on different techniques, such as atomic layer deposition (ALD), to deposit the materials in the seed layer stack within vias having aspect ratios much greater than 5 (e.g., at least 6, at least 7, at least 9, at least 10, at least 12, at least 15, at least 20, etc.). ALD can be used to line the inner surfaces of vias with high aspect ratios because ALD enables conformal coatings regardless of the position and/or orientation of the surfaces being coated and enables high coverage across uneven surfaces. Furthermore, the thickness of films or coatings deposited using ALD can be precisely controlled (e.g., to the sub-nanometer range). While ALD can be employed to deposit materials into high-aspect ratio vias, not all materials are suitable for deposition using ALD techniques. Accordingly, examples disclosed herein identify suitable materials that serve the purposes of the different layers in the seed layer stack while also being capable of deposition through ALD. In this manner, stress in glass cores with high aspect ratio vias (e.g., through glass vias (TGVs)) can be significantly reduced to improve mechanical reliability of the core and increase yields. In particular, simulated experiments have shown examples disclosed herein achieve a reduction in stress in a glass core to less than one half (e.g., one third) the stress experienced in glass cores manufactured using known techniques.

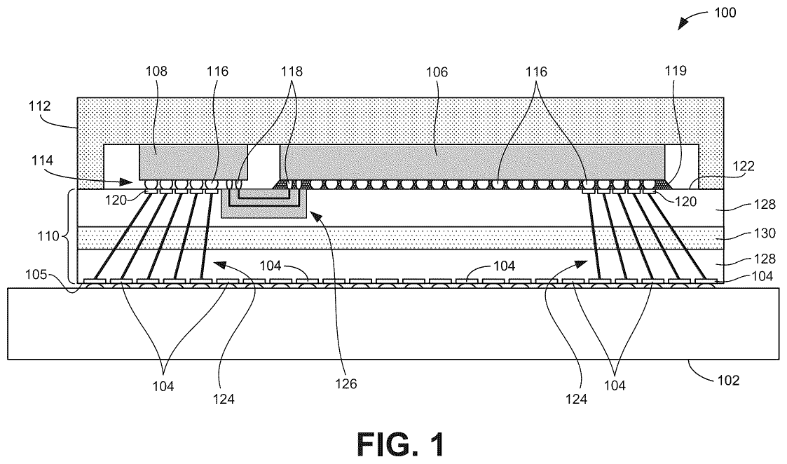

FIG. 1 illustrates an example integrated circuit (IC) package 100 constructed in accordance with teachings disclosed herein. In the illustrated example, the IC package 100 is electrically coupled to a circuit board 102 via an array of contact pads or lands 104 on a mounting surface 105 (e.g., a bottom surface) of the package 100. In some examples, the IC package 100 may include balls, pins, and/or pads, in addition to or instead of the contact pads 104, to enable the electrical coupling of the package 100 to the circuit board 102. In this example, the package 100 includes two semiconductor (e.g., silicon) dies 106, 108 (sometimes also referred to as chips or chiplets) that are mounted to a package substrate 110 and enclosed by a package lid or mold compound 112. Thus, the package substrate 110 is an example means for supporting a semiconductor die. While the example IC package 100 of FIG. 1 includes two dies 106, 108, in other examples, the package 100 may have only one die or more than two dies. In some examples, one of the dies 106, 108 (or a separate die) is embedded in the package substrate 110. The dies 106, 108 can provide any suitable type of functionality (e.g., data processing, memory storage, etc.).

As shown in the illustrated example, each of the dies 106, 108 is electrically and mechanically coupled to the substrate 110 via corresponding arrays of interconnects 114. In FIG. 1, the interconnects are shown as bumps. However, the interconnects 114 may be any other type of electrical connection in addition to or instead of the bumps shown (e.g., balls, pins, pads, wire bonding, etc.). The electrical connections between the dies 106, 108 and the substrate 110 (e.g., the interconnects 114) are sometimes referred to as first level interconnects. By contrast, the electrical connections between the IC package 100 and the circuit board 102 (e.g., the pads 104) are sometimes referred to as second level interconnects. In some examples, the second level interconnects are used to electrically couple the IC package 100 to some component other than a circuit board (e.g., an interposer, another IC package, etc.). In some examples, one or both of the dies 106, 108 may be stacked on top of one or more other dies and/or an interposer. In such examples, the dies 106, 108 are coupled to the underlying die and/or interposer through a first set of first level interconnects and the underlying die and/or interposer may be connected to the package substrate 110 via a separate set of first level interconnects associated with the underlying die and/or interposer. Thus, as used herein, first level interconnects refer to interconnects (e.g., balls, bumps, pins, pads, wire bonding, etc.) between a die and a package substrate or a die and an underlying die and/or interposer.

As shown in FIG. 1, the interconnects 114 of the first level interconnects include two different types of bumps corresponding to core bumps 116 and bridge bumps 118. As used herein, the core bumps 116 are bumps on the dies 106, 108 through which electrical signals pass between the dies 106, 108 and components external to the IC package 100. More particularly, as shown in the illustrated example, when the dies 106, 108 are mounted to the package substrate 110, the core bumps 116 are physically connected and electrically coupled to contact pads 120 on an inner surface 122 of the substrate 110. The contact pads 120 on the inner surface 122 of the package substrate 110 are electrically coupled to the pads 104 on the bottom (external) surface 105 of the substrate 110 (e.g., a surface opposite the inner surface 122) via internal interconnects 124 within the substrate 110. As a result, there is a continuous electrical signal path (e.g., a continuous electrical signal path) between the interconnects 114 of the dies 106, 108 and the pads 104 mounted to the circuit board 102 that pass through the contact pads 120 and the interconnects 124 provided therebetween.

As used herein, the bridge bumps 118 are bumps on the dies 106, 108 through which electrical signals pass between different ones of the dies 106, 108 within the package 100. Thus, as shown in the illustrated example, the bridge bumps 118 of the first die 106 are electrically coupled to the bridge bumps 118 of the second die 108 via an interconnect bridge 126 embedded in the package substrate 110. As represented in FIG. 1, core bumps 116 are typically larger than bridge bumps 118. In some examples, the interconnect bridge 126 and the associated bridge bumps 118 are omitted.

In some examples, an underfill material 119 is disposed between the dies 106, 108 and the package substrate 110 around and/or between the first level interconnects 114 (e.g., around and/or between the core bumps 116 and/or the bridge bumps 118). In the illustrated example, only the first die 106 is associated with the underfill material 119. However, in other examples, both dies 106, 108 are associated with the underfill material 119. In other examples, the underfill material 119 is omitted. In some examples, the mold compound 112 is used as an underfill material that surrounds the first level interconnects 114.

In some examples, the IC package 100 includes additional passive components, such as surface-mount resistors, capacitors, and/or inductors disposed the bottom (external) surface 105 of the package substrate 110 and/or the top (inner) surface 122 of the package substrate 110.

For purposes of illustration, the internal interconnects 124 are shown as straight lines extending directly between the pads 104 on the bottom surface 105 and the contact pads on the inner surface 122. However, in some examples, the internal interconnects 124 are defined by traces or routing in separate conductive (e.g., metal) layers within buildup regions 128 on one or both sides of a substrate core 130 (e.g., a base substrate) in the package substrate 110. In such examples, the buildup regions 128 include dielectric layers to separate the different conductive layers. In such examples, the traces or routing in the different conductive layers are electrically coupled (to define the complete electrical path of the internal interconnects 124) by conductive (e.g., metal) vias extending between the different conductive layers. Further, in some examples, the internal interconnects 124 include vias that extend through the substrate core 130.

In some examples, the substrate core 130 is a glass substrate or glass core. In some examples, glass substrates (e.g., the glass core 130) includes quartz, fused silica, and/or borosilicate glass. In some examples, glass substrates (e.g., the glass core 130) includes at least 20% (by weight) of each of silicon (Si) and oxygen (O). In other examples, glass substrates (e.g., the glass core 130) includes greater amounts of at least one of silicon or oxygen (e.g., at least 25 wt %, at least 30 wt %, at least 35 wt %, at least 40 wt %, etc.). In some examples, glass substrates (e.g., the glass core 130) includes at least 5% (by weight) of aluminum (Al). In some examples, glass substrates (e.g., the glass core 130) include at least one glass layer and do not include epoxy and do not include glass fibers (e.g., does not include an epoxy-based prepreg layer with glass cloth). In some examples, glass substrates (e.g., the glass core 130) correspond to a single piece of glass that extends the full height/thickness of the core. In some examples, the glass core 130 has a rectangular shape that is substantially coextensive, in plan view, with the layers above and below the core (e.g., substantially coextensive with the buildup regions 128). The glass core 130 provides stiffness and mechanical support or strength for the package substrate 110 and the rest of the package 100. Thus, the glass core 130 is an example means for strengthening the package substrate 110. In some examples, the thickness of the glass core 130 is driven by the size (e.g., footprint) of the package 100. For example, in some instances, larger packages 100 include a substrate 110 with a larger (e.g., thicker) core 130 as compared with smaller packages 100 where the core does not need to be as thick.

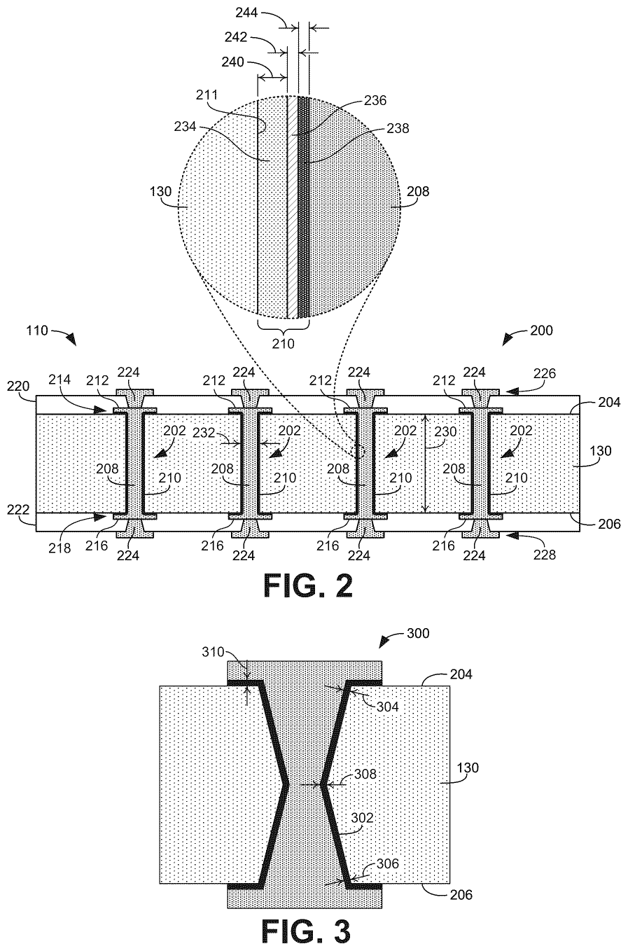

FIG. 2 is a cross-sectional view of an example implementation 200 of the package substrate 110 of FIG. 1 at a point in the fabrication process in which the buildup regions 128 of FIG. 1 are partially formed. Specifically, the package substrate 110 shown in FIG. 2 includes a plurality of through-glass vias (TGVs) 202 (e.g., openings, through-holes, etc.) that extend all the way through the core 130 from a first (outer) surface 204 of the core 130 to a second (outer) surface 206 of the core. The TGVs 202 include a conductive fill material 208 (e.g., plated copper) that has been electroplated onto a seed layer stack 210 that lines walls 211 (sidewalls, inner surfaces) of the TGVs 202. In some examples, the electroplating of the conductive fill material 208 is implemented to fill the TGVs 202. That is, the conductive fill material 208 fills a central region of the TGVs 202.

As shown in the illustrated example, the TGVs 202 are coupled to respective first via pads 212 that extend along the first surface 204 of the core 130 in a first metal layer 214 of the buildup region 128 on the first surface 204. Likewise, the TGVs 202 are coupled to respective second via pads 216 that extend along the second surface 206 of the core 130 in a first metal layer 218 of the buildup region 128 on the second surface 206. In some examples, via pads 212, 216 include a portion of the seed layer stack 210 that extends along the outer surfaces 204, 206 of the core 130. In this example, a first dielectric layer 220 is deposited over the first via pads 212 and the first surface 204 of the core 130 and a second dielectric layer 222 is deposited over the second via pads 216 and the second surface 206 of the core 130. Further, as shown in the illustrated example, additional metal vias 224 extend through respective ones of the dielectric layers 220, 222, to electrical couple the via pads in the first metal layers 214, 218 adjacent the core 130 with second metal layers 226, 228 on opposite sides of the dielectric layers 220, 222. In this example, the TGVs 202 and the associated additional vias 224 define at least portions of the internal interconnects 124 shown in FIG. 1.

As represented in the illustrated example, the TGVs 202 have a height 230 (e.g., a length, a depth) that is significantly greater than a width 232 (e.g., a diameter) of the TGVs 202. Thus, the TGVs 202 have a relatively high height-to-width aspect ratio. In this example, the height 230 of the TGVs corresponds to a thickness of the core 130. As packages continue to increase in size, the thickness of the core 130 and, thus, the height 230 of the TGVs 202 also increases. In some examples, the core 130 thickness (and height 230 of the TGVs 202) can be at least 800 micrometers (μm) or more (e.g., at least 900 μm, at least 1000 μm (1 millimeter (mm)), at least 1.2 mm, at least 1.4 mm, etc.). While core thicknesses (and thus TGV heights 230) are increasing as technology advances, the width 232 of TGVs 202 have remained constant or have even become smaller as technology advances, thereby leading to ever increasing aspect ratios. For instance, the width 232 of TGVs 202 can be significantly less than or equal to approximately 100 μm (e.g., less than or equal to approximately 75 μm, less than or equal to approximately 55 μm, less than or equal to approximately 45 μm, less than or equal to approximately 30 μm, etc.). Thus, based on these dimensions, the aspect ratio of the TGVs 202 can be much greater than 5 (e.g., at least 6, at least 7, at least 9, at least 10, at least 12, at least 15, at least 20, etc.). Such large aspect ratios make it difficult if not impossible to line the walls 211 with materials for the seed layer stack 210 using standard deposition techniques. More particularly, the standard PVD process for depositing a metal seed layer is typically limited to aspect ratios of no more than 5.

One reason for the limitations of PVD processes is that PVD is a directional deposition process that deposits material unevenly depending on the orientation of the surface onto which material is being deposited as well as the position and/or distance of the surface relative to other surface onto which the material is being deposited. That is, PVD results in a non-conformal coating or film on an underlying substrate that differs in thickness depending on the location of the coating or film where the thickness is measured. For instance, when depositing a material onto a substrate that includes a through-hole (such as the TGVs 202 of FIG. 2), far more material will accumulate on the surface of the substrate surrounding the opening of the through-hole with less and less material attaching to the wall of the through-hole the farther into the through-hole one goes. For at least these reasons, attempting to deposit a metal seed layer onto the walls 211 of the TGVs 202 (with high aspect ratios) are likely to result in gaps or voids in the coverage of the walls 211, which may lead to gaps or voids in the conductive fill material 208 electroplated onto such seed layers.

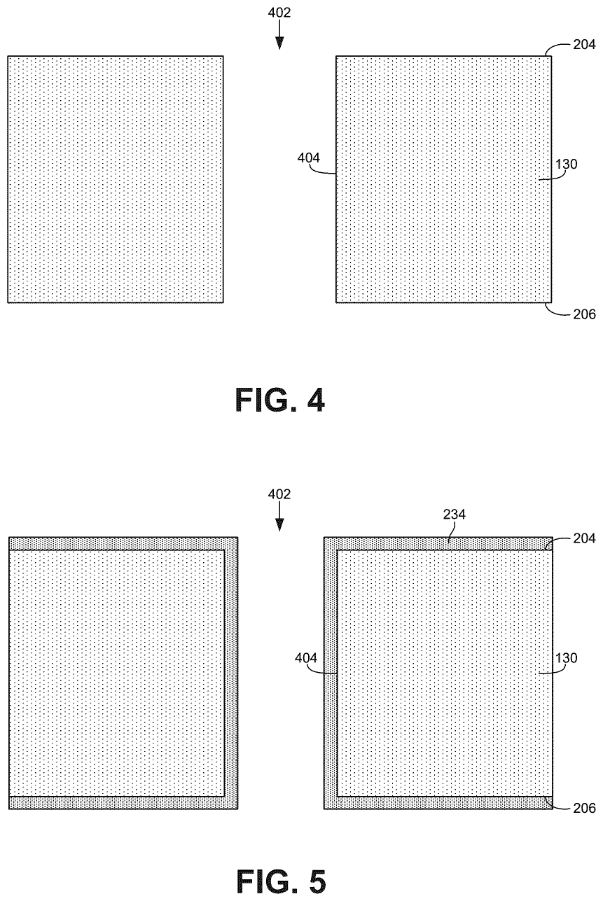

The directional nature of PVD also means that the deposition of material onto an underlying surface requires direct line of sight. However, many TGVs 202 do not have perfectly straight walls 211. Rather, as shown in the example TGV 300 shown schematically in FIG. 3, TGVs 300 often include tapered (e.g., slanted, angled) walls that define overhanging features that prevent direct line of sight deposition. Therefore, the use of PVD is not a viable option to deposit a seed layer within a TGV that can then be used to fill the TGV with electroplated copper. Any one of the TGVs 202 of FIG. 2 may alternatively have a profile similar to the example TGV 300 of FIG. 3. Further, in other examples, TGVs can have any other suitable profile.

Examples disclosed herein overcome the above limitations of PVD through the use of atomic layer deposition (ALD) techniques. Unlike PVD, ALD is not a directional deposition process. ALD provides a conformal coating onto all exterior surfaces of a substrate regardless of whether there is a direct line of sight. That is, unlike PVD, the thickness of a layer of material deposited using ALD can be substantially consistent across all surfaces onto which the material is deposited regardless of the position and/or orientation of the surfaces or their spatial relationship relative to one another. In other words, as shown in FIG. 3, the seed layer 302 has a substantially even thickness with a first thickness 304 at a first end of the TGV 300 that is approximately equal to a second thickness of the seed layer 302 at a second end of the TGV 300. Further, as shown in the illustrated example, the seed layer 302 has a third thickness 306 at a midpoint of the TGV 300 that is approximately equal to the first thickness 304 and approximately equal to the second thickness 306. Further, each of the first, second, and third thicknesses 304, 306, 308 are approximately equal to a fourth thickness 310 of the seed layer 302 on the outer surfaces 204, 206 of the core 130. Stated more generally, in some examples, due to the use of ALD, the seed layer 302 has a thickness that differs by less than 5% between any two points on the seed layer 302. As used herein, different thicknesses are “approximately equal” with there is less than 5% different between the thicknesses. Likewise, as used herein, a “substantially consistent thickness” and a “substantially even thickness” of a layer of material mean the layer has a thickness that varies by less than 5% across the entire area covered by the layer of material.

In some examples, as shown in the inset of FIG. 2, the seed layer stack 210 includes a stack of multiple different layers of materials. In some examples, one or more of the different layers of materials in the seed layer stack 210 are deposited using an ALD process. In this example, the seed layer stack 210 includes a dielectric liner 234 (e.g., a stress reducing liner, a stress buffer layer), a metal seed layer 236 (e.g., a first conductive material, a conductive liner), and an inserter 238 (e.g., a second conductive material, a transition layer). More particularly, in this example, the metal seed layer 236 is between the dielectric liner 234 and the inserter 238. Further, in this example, the dielectric liner 234 is closer to the core 130 than either the metal seed layer 236 or the inserter 238 is to the core 130. Specifically, in this example, the dielectric liner 234 is in contact with the core 130 (e.g., in contact with the sidewalls 211 of the TGVs 202). In some examples, the dielectric liner 234 is omitted such that the metal seed layer 236 is directly in contact with the core 130. As shown in the illustrated example, the inserter 238 is closer to the conductive fill material 208 than either the dielectric liner 234 or the metal seed layer 236 is to the conductive fill material 208. Specifically, in this example, the inserter 238 is in contact with the conductive fill material 208. In some examples, the inserter 238 is omitted such that the metal seed layer 236 is in direct contact with the conductive fill material 208.

In some examples, the dielectric liner 234 is a relatively low modulus material (e.g., materials with a Young's modulus of less than 2 Gigapascals (GPa)) that reduces stress resulting from the CTE mismatch between the glass core 130 and the metal used for the conductive fill material 208. In some examples, the conductive fill material 208 includes copper. In other examples, a different metal can be used for the conductive fill material 208. In some examples, the dielectric liner 234 includes a polymer (e.g., a parylene, polyimide, an epoxy), SiₓO_{y}C_{z}H_{w}, SiNₓC_{y}H_{z}, and/or SiOₓ. In some examples, the dielectric liner 234 includes an organic material that contains an inorganic filler. In some examples, the dielectric liner 234 includes a fiber reinforced polymer. In some examples, the dielectric liner 234 includes multiple layers of different materials.

In some examples, the metal seed layer 236 includes an electrically conductive material to carry a current applied to the substrate (e.g., the core 130) to facilitate the electroplating of the conductive fill material 208. Further, in this example, the metal seed layer 236 includes materials capable of being deposited using ALD. More particularly, in some examples, the metal seed layer 236 includes at least one of ruthenium or copper and/or oxides of such metals. However, other materials may also be employed for the metal seed layer 236 (e.g., molybdenum, titanium, vanadium, chromium, iron, cobalt, nickel, zinc, zirconium, rhodium, palladium, silver, cadmium, tantalum, tungsten, iridium, platinum, gold, etc. and/or oxides of such metals). In some examples, the metal seed layer 236 includes any suitable electrically conductive metal oxide layer (e.g., zinc oxide). In some examples, the metal seed layer 236 does not include titanium or at least includes only trace amounts of titanium (e.g., less than 1 wt %, less than 0.5 wt %, less than 0.1 wt %, etc.). In some examples, the metal seed layer 236 includes multiple layers of different materials. In some examples, the metal seed layer 236 includes different materials than the conductive fill material 208. That is, in some examples, the metal seed layer 236 includes a different composition from the conductive fill material 208.

In this example, the inserter 238 serves as a transition layer between the metal seed layer 236 and the conductive fill material 208 to improve adhesion between the metal seed layer 236 and the conductive fill material 208. In some examples, the inserter 238 includes conductive materials capable of being deposited using ALD. In some examples, the inserter 238 includes at least one of titanium or copper. In some examples, the inserter 238 includes at least one of TiN, SiN, TaN, or SiOx. In some examples, the inserter 238 includes multiple layers of different materials.

In some examples, each of the layers of materials in the seed layer stack 210 have different thicknesses. More particularly, in some examples, the dielectric liner 234 has a first thickness 240 that is significantly greater than a second thickness 242 of the metal seed layer 236 and significantly greater than a third thickness 244 of the inserter 238. The greater thickness of the dielectric liner 234 is to provide stress relief as discussed above. In some examples, the first thickness 240 of the dielectric liner is at least 300 nanometers (nm) (0.3 μm) and may be significantly thicker (e.g., at least 0.5 μm, at least 0.75 μm, at least 1 μm, at least 2 μm, at least 5 μm, at least 7.5μm, at least 9 μm, etc.). By contrast, in some examples, the second thickness 242 of the metal seed layer 236 is less than or equal to approximately 100 nm (e.g., less than or equal to approximately 75 nm, less than or equal to approximately 50 nm, less than or equal to approximately 25 nm, less than or equal to approximately 10 nm, less than or equal to approximately 5 nm, less than or equal to approximately 3 nm, etc.) and may be as thin as approximately 1 nm or less. In some examples, the second thickness 242 is greater than 100 nm. In some examples, the third thickness 244 of the inserter 238 is also less than or equal to approximately 100 nm (e.g., less than or equal to approximately 75 nm, less than or equal to approximately 50 nm, less than or equal to approximately 25 nm, less than or equal to approximately 10 nm, less than or equal to approximately 5 nm, less than or equal to approximately 3 nm, etc.) and may be as thin as approximately 1 nm or less. In some examples, the third thickness 244 is greater than 100 nm. In some examples, the third thickness 244 of the inserter 238 is less than or equal to the second thickness 242 of the metal seed layer 236. In other examples, the third thickness 244 of the inserter 238 is greater than the second thickness 242 of the metal seed layer 236.

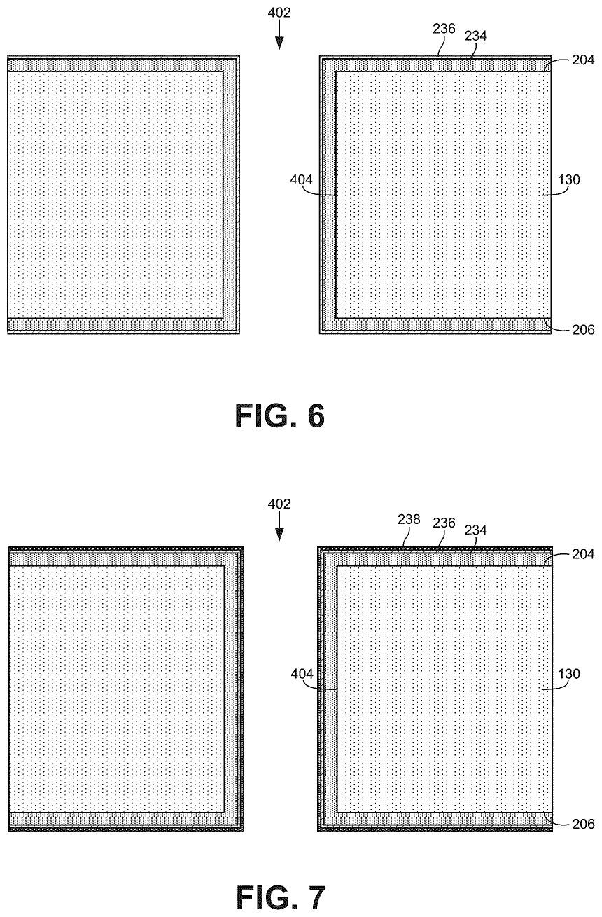

FIGS. 4-9 illustrate different stages during an example fabrication process to manufacture a plated through-hole or TGV such as the TGVs 202, 300 shown in FIGS. 2 and/or 3. More particularly, FIG. 4 represents the stage of fabrication following the creation of a via 402 (e.g., a TGV, a through-hole, an opening) extending through the glass core 130. In this example, the TGV 402 is defined by an inner sidewall 404 that extends in a straight line from the first and second (outer) surfaces 204, 206 of the core 130. More particularly, in this example the sidewall 404 extends in a direction substantially perpendicular (e.g., within 5 degrees of perpendicular) to the outer surfaces 204, 206. However, in other examples, the sidewall 404 may extend at non-perpendicular angles relative to the outer surfaces 204, 206. Further, in some examples, the sidewall 404 may not be a continuously straight line. Rather, in some examples, the sidewall 404 may define an hour-glass shape, such as is shown in the illustrated example of FIG. 3. In other examples, the sidewall 404 can have any other suitable shape or profile.

FIG. 5 represents the stage of fabrication following the deposition of the dielectric liner 234 onto exposed surfaces of the core 130. In this example, the exposed surfaces include the outer surfaces 204, 206 of the core 130 as well as the sidewall 404 of the TGV 402 in the core 130. In some examples, the dielectric liner 234 is deposited via spin coating, slit coating, chemical vapor deposition (CVD), or vacuum lamination. In some examples, these deposition processes result in the TGV 402 being substantially or completely filled by the dielectric liner 234. In such examples, a subsequent laser drilling process through the filled TGV 402 is performed to remove the dielectric liner 234 from the central region of the TGV 402 so that the dielectric liner 234 is limited to (e.g., lines) the sidewall 404 of the TGV 402.

FIG. 6 represents a subsequent stage of fabrication after the deposition of the metal seed layer 236 onto the dielectric liner 234. In this example, because the TGV 402 has a relatively high aspect ratio (e.g., above 5), standard PVD processes are unavailable. Accordingly, in some examples, the metal seed layer 236 is deposited through an ALD process. More particularly, in some examples, the metal seed layer 236 is deposited using thermal ALD or plasma enhanced ALD.

FIG. 7 represents a subsequent stage of fabrication after the deposition of the inserter 238 onto the metal seed layer 236. In some examples, the deposition process employed to deposit the inserter 238 may depend on the material used for the inserter 238. For instance, if the inserter 238 includes a titanium/copper layer, the inserter can be deposited via sputtering. In other examples, if the inserter 238 is to be a dry deposited seed metal (e.g., copper or other suitable metal), an ALD process can be used. As discussed above, the dielectric liner 234, the metal seed layer 236, and the inserter 238 collectively correspond to the seed layer stack 210 discussed above in connection with FIGS. 2 and 3. In some examples, the inserter 238 is omitted.

FIG. 8 represents a subsequent stage of fabrication after the deposition of the conductive fill material 208 onto the metal seed layer 236 (and the inserter 238). In some examples, the conductive fill material 208 is deposited via electroplating using the metal seed layer 236 (and inserter 238) as the conductive underlying surface. As shown in the illustrated example, the conductive fill material 208 is electroplated to fill a central region of (e.g., the remaining open space within) the TGV 402. Further, as shown in FIG. 8, the conductive fill material 208 also extends across the outer surfaces 204, 260 of the core 130.

FIG. 9 represents a subsequent stage of fabrication after the removal of excess portions of the conductive fill material 208, the inserter 238, and/or the metal seed layer 236 on the outer surfaces 204, 206 of the core 130. In some examples, the excess portions of material are removed via an etching process (e.g., a wet etch, a dry etch, etc.). As shown in the illustrated example of FIG. 9, the remaining portions of the material on the outer surfaces 204, 206 define first and second via pads 902, 904 at either end of the TGV 402.

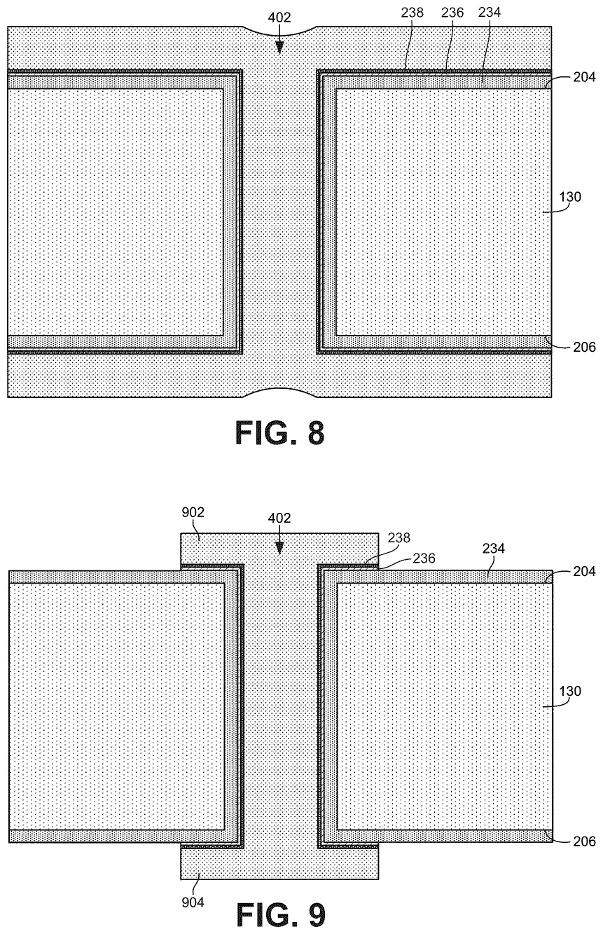

FIG. 10 is a flowchart representative of an example method 1000 to manufacture any one of the example TGVs 202, 300, 402 of FIGS. 2-9. In some examples, some or all of the operations outlined in the example method of FIG. 10 are performed automatically by fabrication equipment that is programmed to perform such operations. Although the example method of manufacture is described with reference to the flowchart illustrated in FIG. 10, many other methods may alternatively be used. For example, the order of execution of the blocks may be changed, and/or some of the blocks described may be combined, divided, re-arranged, omitted, eliminated, and/or implemented in any other way. Further, in some examples, additional processing operations can be performed before, between, and/or after any of the blocks represented in the illustrated example.

Turning to FIG. 10 in detail, the example process begins at block 1002 by providing high aspect ratio via(s) (e.g., the vias 202, 300, 402) in a glass core (e.g., the core 130). The operation(s) associated with block 1002 are represented by FIG. 4 as described above. At block 1004, the example process involves depositing a dielectric liner (e.g., the dielectric liner 234) across outer surfaces (e.g., the surfaces 204, 206) of the glass core 130 and along sidewalls (e.g., the sidewalls 211, 404) of the via(s) 202, 300, 402. The dielectric liner 234 serves as a stress buffer between the glass core 130 and the subsequently added metal layers. The operation(s) associated with block 1004 are represented by FIG. 5 as described above.

At block 1006, the example process involves depositing a metal seed layer (e.g., the metal seed layer 236) onto the dielectric liner 234 using atomic layer deposition (ALD). In this example, ALD is employed because of the high aspect ratio of the via(s) 202, 300, 402. The operation(s) associated with block 1006 are represented by FIG. 6 as described above. At block 1008, the example process involves depositing an inserter (e.g., the inserter 238) onto the metal seed layer 236. In some examples, block 1008 is omitted. The operation(s) associated with block 1008 are represented by FIG. 7 as described above. At block 1010, the example process involves electroplating a conductive fill material (e.g., the conductive fill material 208) onto the inserter 238 (and/or the metal seed layer 236) to fill the via(s) 202, 300, 402. The operation(s) associated with block 1010 are represented by FIG. 8 as described above. At block 1012, the example process involves removing excess material. Specifically, portions of the conductive fill material 208, the inserter 238, and/or the metal seed layer 236 are removed (e.g., via etching) to define the first metal layers (e.g., the first metal layers 214, 218) on the outer surfaces 204, 206 of the glass core 130. The operation(s) associated with block 1012 are represented by FIG. 9 as described above. Thereafter, the example process ends, and the resulting apparatus may proceed to subsequent fabrication processes to, for example, add the buildup regions 128 onto the glass core 130.

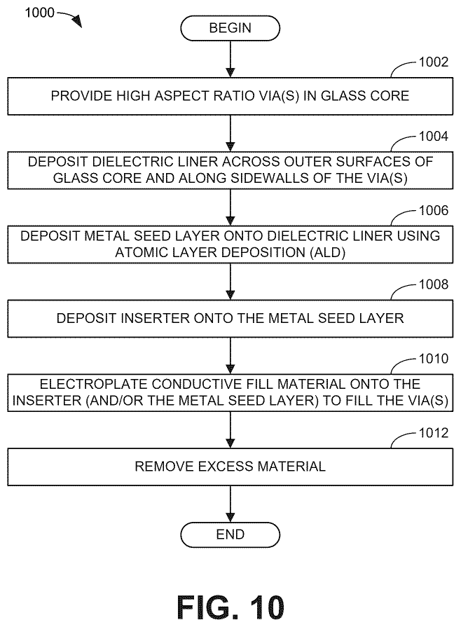

The example TGVs 202, 300, 402 disclosed herein may be included in any suitable electronic component. FIGS. 11-14 illustrate various examples of apparatus that may include and/or be included in the example IC package 100 of FIG. 1 that contains the example TGVs 202, 300, 402 disclosed herein.

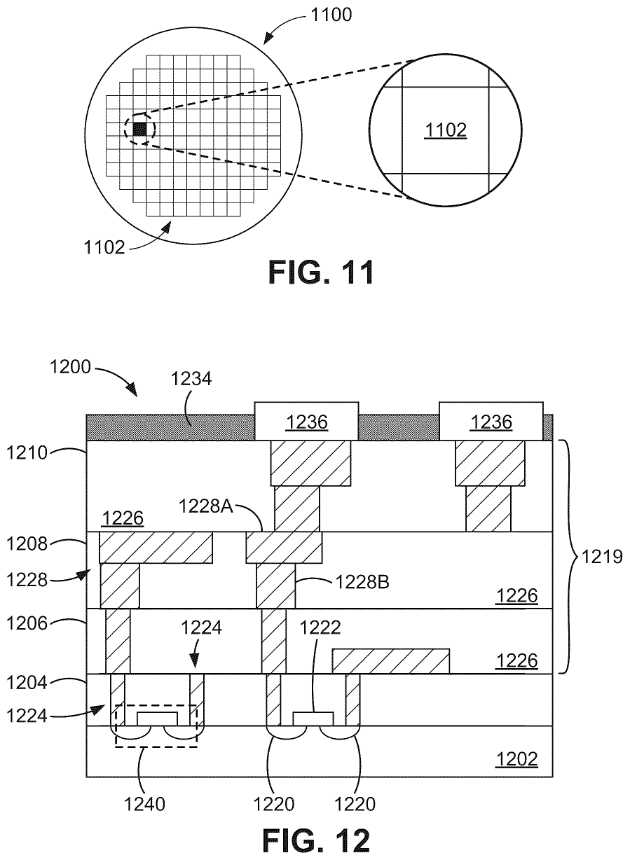

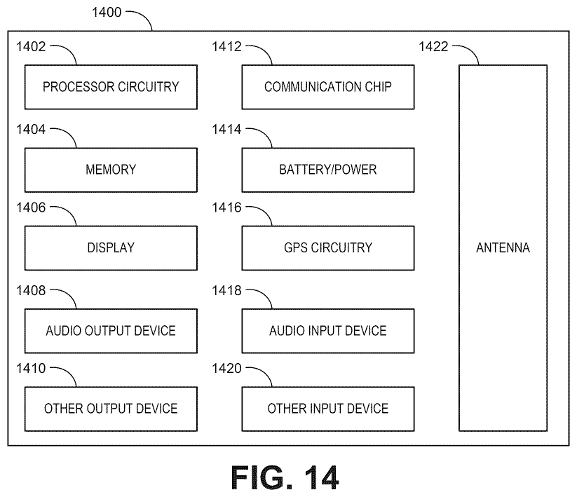

FIG. 11 is a top view of a wafer 1100 and dies 1102 that may be included in the IC package 100 of FIG. 1 (e.g., as any suitable ones of the dies 106, 108) with a substrate that includes one or more of the example TGVs 202, 300, 402 disclosed herein. The wafer 1100 includes semiconductor material and one or more dies 1102 having circuitry. Each of the dies 1102 may be a repeating unit of a semiconductor product. After the fabrication of the semiconductor product is complete, the wafer 1100 may undergo a singulation process in which the dies 1102 are separated from one another to provide discrete “chips.” The die 1102 includes one or more transistors (e.g., some of the transistors 1240 of FIG. 12, discussed below), supporting circuitry to route electrical signals to the transistors, passive components (e.g., traces, resistors, capacitors, inductors, and/or other circuitry), and/or any other components. In some examples, the die 1102 may include and/or implement a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuitry or electronics. Multiple ones of these devices may be combined on a single die 1102. For example, a memory array of multiple memory circuits may be formed on a same die 1102 as programmable circuitry (e.g., the processor circuitry 1402 of FIG. 14) and/or other logic circuitry. Such memory may store information for use by the programmable circuitry. The example IC package 100 disclosed herein may be manufactured using a die-to-wafer assembly technique in which some dies are attached to a wafer 1100 that includes others of the dies, and the wafer 1100 is subsequently singulated.

FIG. 12 is a cross-sectional side view of an IC device 1200 that may be included in the example IC package 100 (e.g., in any one of the dies 106, 108) with a substrate that includes one or more of the example TGVs 202, 300, 402 disclosed herein. One or more of the IC devices 1200 may be included in one or more dies 1102 (FIG. 11). The IC device 1200 may be formed on a die substrate 1202 (e.g., the wafer 1100 of FIG. 11) and may be included in a die (e.g., the die 1102 of FIG. 11). The die substrate 1202 may be a semiconductor substrate including semiconductor materials including, for example, n-type or p-type materials systems (or a combination of both). The die substrate 1202 may include, for example, a crystalline substrate formed using a bulk silicon or a silicon-on-insulator (SOI) substructure. In some examples, the die substrate 1202 may be formed using alternative materials, which may or may not be combined with silicon, that include but are not limited to germanium, indium antimonide, lead telluride, indium arsenide, indium phosphide, gallium arsenide, or gallium antimonide. Further materials classified as group II-VI, III-V, or IV may also be used to form the die substrate 1202. Although a few examples of materials from which the die substrate 1202 may be formed are described here, any material that may serve as a foundation for an IC device 1200 may be used. The die substrate 1202 may be part of a singulated die (e.g., the dies 1102 of FIG. 11) or a wafer (e.g., the wafer 1100 of FIG. 11).

The IC device 1200 may include one or more device layers 1204 disposed on and/or above the die substrate 1202. The device layer 1204 may include features of one or more transistors 1240 (e.g., metal oxide semiconductor field-effect transistors (MOSFETs)) formed on the die substrate 1202. The device layer 1204 may include, for example, one or more source and/or drain (S/D) regions 1220, a gate 1222 to control current flow between the S/D regions 1220, and one or more S/D contacts 1224 to route electrical signals to/from the S/D regions 1220. The transistors 1240 may include additional features not depicted for the sake of clarity, such as device isolation regions, gate contacts, and the like. The transistors 1240 are not limited to the type and configuration depicted in FIG. 12 and may include a wide variety of other types and/or configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon and nanowire transistors.

Each transistor 1240 may include a gate 1222 including a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and/or zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and/or lead zinc niobate. In some examples, an annealing process may be carried out on the gate dielectric to improve its quality when a high-k material is used.

The gate electrode may be formed on the gate dielectric and may include at least one p-type work function metal or n-type work function metal, depending on whether the transistor 1240 is to be a p-type metal oxide semiconductor (PMOS) or an n-type metal oxide semiconductor (NMOS) transistor. In some implementations, the gate electrode may include a stack of two or more metal layers, where one or more metal layers are work function metal layers and at least one metal layer is a fill metal layer. Further metal layers may be included, such as a barrier layer. For a PMOS transistor, metals that may be used for the gate electrode include, but are not limited to, ruthenium, palladium, platinum, cobalt, nickel, conductive metal oxides (e.g., ruthenium oxide), and/or any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and/or aluminum carbide), and/or any of the metals discussed above with reference to a PMOS transistor (e.g., for work function tuning).

In some examples, when viewed as a cross-section of the transistor 1240 along the source-channel-drain direction, the gate electrode may include a U-shaped structure that includes a bottom portion substantially parallel to the surface of the die substrate 1202 and two sidewall portions that are substantially perpendicular to the top surface of the die substrate 1202. In other examples, at least one of the metal layers that form the gate electrode may be a planar layer that is substantially parallel to the top surface of the die substrate 1202 and does not include sidewall portions substantially perpendicular to the top surface of the die substrate 1202. In other examples, the gate electrode may include a combination of U-shaped structures and/or planar, non-U-shaped structures. For example, the gate electrode may include one or more U-shaped metal layers formed atop one or more planar, non-U-shaped layers.

In some examples, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and/or silicon oxynitride. Processes for forming sidewall spacers are well known in the art and generally include deposition and etching process operations. In some examples, a plurality of spacer pairs may be used; for instance, two pairs, three pairs, or four pairs of sidewall spacers may be formed on opposing sides of the gate stack.

The S/D regions 1220 may be formed within the die substrate 1202 adjacent to the gate 1222 of corresponding transistor(s) 1240. The S/D regions 1220 may be formed using an implantation/diffusion process or an etching/deposition process, for example. In the former process, dopants such as boron, aluminum, antimony, phosphorous, or arsenic may be ion-implanted into the die substrate 1202 to form the S/D regions 1220. An annealing process that activates the dopants and causes them to diffuse farther into the die substrate 1202 may follow the ion-implantation process. In the latter process, the die substrate 1202 may first be etched to form recesses at the locations of the S/D regions 1220. An epitaxial deposition process may then be carried out to fill the recesses with material that is used to fabricate the S/D regions 1220. In some implementations, the S/D regions 1220 may be fabricated using a silicon alloy such as silicon germanium or silicon carbide. In some examples, the epitaxially deposited silicon alloy may be doped in situ with dopants such as boron, arsenic, or phosphorous. In some examples, the S/D regions 1220 may be formed using one or more alternate semiconductor materials such as germanium or a group III-V material or alloy. In further examples, one or more layers of metal and/or metal alloys may be used to form the S/D regions 1220.

Electrical signals, such as power and/or input/output (I/O) signals, may be routed to and/or from the devices (e.g., transistors 1240) of the device layer 1204 through one or more interconnect layers disposed on the device layer 1204 (illustrated in FIG. 12 as interconnect layers 1206-1210). For example, electrically conductive features of the device layer 1204 (e.g., the gate 1222 and the S/D contacts 1224) may be electrically coupled with the interconnect structures 1228 of the interconnect layers 1206-1210. The one or more interconnect layers 1206-1210 may form a metallization stack (also referred to as an “ILD stack”) 1219 of the IC device 1200.

The interconnect structures 1228 may be arranged within the interconnect layers 1206-1210 to route electrical signals according to a wide variety of designs (in particular, the arrangement is not limited to the particular configuration of interconnect structures 1228 depicted in FIG. 12). Although a particular number of interconnect layers 1206-1210 is depicted in FIG. 12, examples of the present disclosure include IC devices having more or fewer interconnect layers than depicted.

In some examples, the interconnect structures 1228 may include lines 1228a and/or vias 1228b filled with an electrically conductive material such as a metal. The lines 1228a may be arranged to route electrical signals in a direction of a plane that is substantially parallel with a surface of the die substrate 1202 upon which the device layer 1204 is formed. For example, the lines 1228a may route electrical signals in a direction in and/or out of the page from the perspective of FIG. 12. The vias 1228b may be arranged to route electrical signals in a direction of a plane that is substantially perpendicular to the surface of the die substrate 1202 upon which the device layer 1204 is formed. In some examples, the vias 1228b may electrically couple lines 1228a of different interconnect layers 1206-1210 together.

The interconnect layers 1206-1210 may include a dielectric material 1226 disposed between the interconnect structures 1228, as shown in FIG. 12. In some examples, the dielectric material 1226 disposed between the interconnect structures 1228 in different ones of the interconnect layers 1206-1210 may have different compositions; in other examples, the composition of the dielectric material 1226 between different interconnect layers 1206-1210 may be the same.

A first interconnect layer 1206 (referred to as Metal 1 or “M1”) may be formed directly on the device layer 1204. In some examples, the first interconnect layer 1206 may include lines 1228a and/or vias 1228b, as shown. The lines 1228a of the first interconnect layer 1206 may be coupled with contacts (e.g., the S/D contacts 1224) of the device layer 1204.

A second interconnect layer 1208 (referred to as Metal 2 or “M2”) may be formed directly on the first interconnect layer 1206. In some examples, the second interconnect layer 1208 may include vias 1228b to couple the lines 1228a of the second interconnect layer 1208 with the lines 1228a of the first interconnect layer 1206. Although the lines 1228a and the vias 1228b are structurally delineated with a line within each interconnect layer (e.g., within the second interconnect layer 1208) for the sake of clarity, the lines 1228a and the vias 1228b may be structurally and/or materially contiguous (e.g., simultaneously filled during a dual-damascene process) in some examples.

A third interconnect layer 1210 (referred to as Metal 3 or “M3”) (and additional interconnect layers, as desired) may be formed in succession on the second interconnect layer 1208 according to similar techniques and/or configurations described in connection with the second interconnect layer 1208 or the first interconnect layer 1206. In some examples, the interconnect layers that are “higher up” in the metallization stack 1219 in the IC device 1200 (i.e., further away from the device layer 1204) may be thicker.

The IC device 1200 may include a solder resist material 1234 (e.g., polyimide or similar material) and one or more conductive contacts 1236 formed on the interconnect layers 1206-1210. In FIG. 12, the conductive contacts 1236 are illustrated as taking the form of bond pads. The conductive contacts 1236 may be electrically coupled with the interconnect structures 1228 and configured to route the electrical signals of the transistor(s) 1240 to other external devices. For example, solder bonds may be formed on the one or more conductive contacts 1236 to mechanically and/or electrically couple a chip including the IC device 1200 with another component (e.g., a circuit board). The IC device 1200 may include additional or alternate structures to route the electrical signals from the interconnect layers 1206-1210; for example, the conductive contacts 1236 may include other analogous features (e.g., posts) that route the electrical signals to external components.

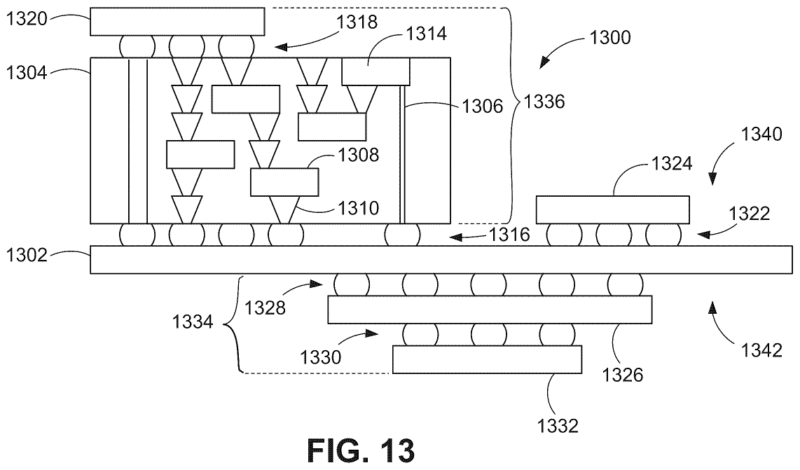

FIG. 13 is a cross-sectional side view of an IC device assembly 1300 that may include the example IC package 100 of FIG. 1 with a substrate that includes one or more of the example TGVs 202, 300, 402 disclosed herein. In some examples, the IC device assembly corresponds to the example IC package 100 of FIG. 1. The IC device assembly 1300 includes a number of components disposed on a circuit board 1302 (which may be, for example, a motherboard). The IC device assembly 1300 includes components disposed on a first face 1340 of the circuit board 1302 and an opposing second face 1342 of the circuit board 1302; generally, components may be disposed on one or both faces 1340 and 1342. Any of the IC packages discussed below with reference to the IC device assembly 2200 may take the form of the example IC package 100 of FIG. 1.

In some examples, the circuit board 1302 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1302. In other examples, the circuit board 1302 may be a non-PCB substrate.

The IC device assembly 1300 illustrated in FIG. 13 includes a package-on-interposer structure 1336 coupled to the first face 1340 of the circuit board 1302 by coupling components 1316. The coupling components 1316 may electrically and mechanically couple the package-on-interposer structure 1336 to the circuit board 1302, and may include solder balls (as shown in FIG. 13), male and female portions of a socket, an adhesive, an underfill material, and/or any other suitable electrical and/or mechanical coupling structure.

The package-on-interposer structure 1336 may include an IC package 1320 coupled to an interposer 1304 by coupling components 1318. The coupling components 1318 may take any suitable form for the application, such as the forms discussed above with reference to the coupling components 1316. Although a single IC package 1320 is shown in FIG. 13, multiple IC packages may be coupled to the interposer 1304; indeed, additional interposers may be coupled to the interposer 1304. The interposer 1304 may provide an intervening substrate used to bridge the circuit board 1302 and the IC package 1320. The IC package 1320 may be or include, for example, a die (the die 1102 of FIG. 11), an IC device (e.g., the IC device 1200 of FIG. 12), or any other suitable component. Generally, the interposer 1304 may spread a connection to a wider pitch or reroute a connection to a different connection. For example, the interposer 1304 may couple the IC package 1320 (e.g., a die) to a set of BGA conductive contacts of the coupling components 1316 for coupling to the circuit board 1302. In the example illustrated in FIG. 13, the IC package 1320 and the circuit board 1302 are attached to opposing sides of the interposer 1304; in other examples, the IC package 1320 and the circuit board 1302 may be attached to a same side of the interposer 1304. In some examples, three or more components may be interconnected by way of the interposer 1304.

In some examples, the interposer 1304 may be formed as a PCB, including multiple metal layers separated from one another by layers of dielectric material and interconnected by electrically conductive vias. In some examples, the interposer 1304 may be formed of an epoxy resin, a fiberglass-reinforced epoxy resin, an epoxy resin with inorganic fillers, a ceramic material, or a polymer material such as polyimide. In some examples, the interposer 1304 may be formed of alternate rigid or flexible materials that may include the same materials described above for use in a semiconductor substrate, such as silicon, germanium, and other group III-V and group IV materials. The interposer 1304 may include metal interconnects 1308 and vias 1310, including but not limited to through-silicon vias (TSVs) 1306. The interposer 1304 may further include embedded devices 1314, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1304. The package-on-interposer structure 1336 may take the form of any of the package-on-interposer structures known in the art.

The IC device assembly 1300 may include an IC package 1324 coupled to the first face 1340 of the circuit board 1302 by coupling components 1322. The coupling components 1322 may take the form of any of the examples discussed above with reference to the coupling components 1316, and the IC package 1324 may take the form of any of the examples discussed above with reference to the IC package 1320.

The IC device assembly 1300 illustrated in FIG. 13 includes a package-on-package structure 1334 coupled to the second face 1342 of the circuit board 1302 by coupling components 1328. The package-on-package structure 1334 may include a first IC package 1326 and a second IC package 1332 coupled together by coupling components 1330 such that the first IC package 1326 is disposed between the circuit board 1302 and the second IC package 1332. The coupling components 1328, 1330 may take the form of any of the examples of the coupling components 1316 discussed above, and the IC packages 1326, 1332 may take the form of any of the examples of the IC package 1320 discussed above. The package-on-package structure 1334 may be configured in accordance with any of the package-on-package structures known in the art.

FIG. 14 is a block diagram of an example electrical device 1400 that may include one or more of the example IC package 100 of FIG. 1 with a substrate that includes one or more of the example TGVs 202, 300, 402 disclosed herein. For example, any suitable ones of the components of the electrical device 1400 may include one or more of the device assemblies 1300, IC devices 1200, or dies 1102 disclosed herein, and may be arranged in the example IC package 100. A number of components are illustrated in FIG. 14 as included in the electrical device 1400, but any one or more of these components may be omitted or duplicated, as suitable for the application. In some examples, some or all of the components included in the electrical device 1400 may be attached to one or more motherboards. In some examples, some or all of these components are fabricated onto a single system-on-a-chip (SoC) die.

Additionally, in various examples, the electrical device 1400 may not include one or more of the components illustrated in FIG. 14, but the electrical device 1400 may include interface circuitry for coupling to the one or more components. For example, the electrical device 1400 may not include a display 1406, but may include display interface circuitry (e.g., a connector and driver circuitry) to which a display 1406 may be coupled. In another set of examples, the electrical device 1400 may not include an audio input device 1418 (e.g., microphone) or an audio output device 1408 (e.g., a speaker, a headset, earbuds, etc.), but may include audio input or output device interface circuitry (e.g., connectors and supporting circuitry) to which an audio input device 1418 or audio output device 1408 may be coupled.

The electrical device 1400 may include programmable circuitry 1402 (e.g., one or more processing devices). The programmable circuitry 1402 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The electrical device 1400 may include a memory 1404, which may itself include one or more memory devices such as volatile memory (e.g., dynamic random access memory (DRAM)), nonvolatile memory (e.g., read-only memory (ROM)), flash memory, solid state memory, and/or a hard drive. In some examples, the memory 1404 may include memory that shares a die with the programmable circuitry 1402. This memory may be used as cache memory and may include embedded dynamic random access memory (eDRAM) or spin transfer torque magnetic random access memory (STT-MRAM).

In some examples, the electrical device 1400 may include a communication chip 1412 (e.g., one or more communication chips). For example, the communication chip 1412 may be configured for managing wireless communications for the transfer of data to and from the electrical device 1400. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some examples they might not.

The communication chip 1412 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-1205 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1412 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1412 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1412 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1412 may operate in accordance with other wireless protocols in other examples. The electrical device 1400 may include an antenna 1422 to facilitate wireless communications and/or to receive other wireless communications (such as AM or FM radio transmissions).

In some examples, the communication chip 1412 may manage wired communications, such as electrical, optical, or any other suitable communication protocols (e.g., the Ethernet). As noted above, the communication chip 1412 may include multiple communication chips. For instance, a first communication chip 1412 may be dedicated to shorter-range wireless communications such as Wi-Fi or Bluetooth, and a second communication chip 1412 may be dedicated to longer-range wireless communications such as global positioning system (GPS), EDGE, GPRS, CDMA, WiMAX, LTE, EV-DO, or others. In some examples, a first communication chip 1412 may be dedicated to wireless communications, and a second communication chip 1412 may be dedicated to wired communications.

The electrical device 1400 may include battery/power circuitry 1414. The battery/power circuitry 1414 may include one or more energy storage devices (e.g., batteries or capacitors) and/or circuitry for coupling components of the electrical device 1400 to an energy source separate from the electrical device 1400 (e.g., AC line power).

The electrical device 1400 may include a display 1406 (or corresponding interface circuitry, as discussed above). The display 1406 may include any visual indicators, such as a heads-up display, a computer monitor, a projector, a touchscreen display, a liquid crystal display (LCD), a light-emitting diode display, or a flat panel display.

The electrical device 1400 may include an audio output device 1408 (or corresponding interface circuitry, as discussed above). The audio output device 1408 may include any device that generates an audible indicator, such as speakers, headsets, or earbuds.

The electrical device 1400 may include an audio input device 1418 (or corresponding interface circuitry, as discussed above). The audio input device 1418 may include any device that generates a signal representative of a sound, such as microphones, microphone arrays, or digital instruments (e.g., instruments having a musical instrument digital interface (MIDI) output).

The electrical device 1400 may include GPS circuitry 1416. The GPS circuitry 1416 may be in communication with a satellite-based system and may receive a location of the electrical device 1400, as known in the art.

The electrical device 1400 may include any other output device 1410 (or corresponding interface circuitry, as discussed above). Examples of the other output device 1410 may include an audio codec, a video codec, a printer, a wired or wireless transmitter for providing information to other devices, or an additional storage device.

The electrical device 1400 may include any other input device 1420 (or corresponding interface circuitry, as discussed above). Examples of the other input device 1420 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 1400 may have any desired form factor, such as a hand-held or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server or other networked computing component, a printer, a scanner, a monitor, a set-top box, an entertainment control unit, a vehicle control unit, a digital camera, a digital video recorder, or a wearable electrical device. In some examples, the electrical device 1400 may be any other electronic device that processes data.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities, etc., the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities, etc., the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

Notwithstanding the foregoing, in the case of referencing a semiconductor device (e.g., a transistor), a semiconductor die containing a semiconductor device, and/or an integrated circuit (IC) package containing a semiconductor die during fabrication or manufacturing, “above” is not with reference to Earth, but instead is with reference to an underlying substrate on which relevant components are fabricated, assembled, mounted, supported, or otherwise provided. Thus, as used herein and unless otherwise stated or implied from the context, a first component within a semiconductor die (e.g., a transistor or other semiconductor device) is “above” a second component within the semiconductor die when the first component is farther away from a substrate (e.g., a semiconductor wafer) during fabrication/manufacturing than the second component on which the two components are fabricated or otherwise provided. Similarly, unless otherwise stated or implied from the context, a first component within an IC package (e.g., a semiconductor die) is “above” a second component within the IC package during fabrication when the first component is farther away from a printed circuit board (PCB) to which the IC package is to be mounted or attached. It is to be understood that semiconductor devices are often used in orientation different than their orientation during fabrication. Thus, when referring to a semiconductor device (e.g., a transistor), a semiconductor die containing a semiconductor device, and/or an integrated circuit (IC) package containing a semiconductor die during use, the definition of “above” in the preceding paragraph (i.e., the term “above” describes the relationship of two parts relative to Earth) will likely govern based on the usage context.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified herein.

As used herein “substantially real time” refers to occurrence in a near instantaneous manner recognizing there may be real world delays for computing time, transmission, etc. Thus, unless otherwise specified, “substantially real time” refers to real time +1 second.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example an integrated circuit may be implemented as one or more of an ASIC, an FPGA, a chip, a microchip, programmable circuitry, a semiconductor substrate coupling multiple circuit elements, a system on chip (SoC), etc.

From the foregoing, it will be appreciated that example systems, apparatus, articles of manufacture, and methods have been disclosed that enable the fabrication of high aspect ratio plated vias within a glass core. Plating metal (e.g., copper) within through-glass vias creates the risk of failures due to high stress imposed on the glass core as a result of the CTE mismatch between glass and the plated metal. However, examples disclosed herein mitigate this concern through the use of a dielectric liner between the glass core and the plated metal that serves as a stress buffer.

A further challenge with electroplating high aspect ratio vias is the inability to obtain full coverage of the inner sidewalls of the vias using standard deposition techniques. Examples disclosed herein overcome these challenges by employing atomic layer deposition (ALD) to deposit a metal seed layer within the vias. Not all conductive materials suitable for a metal seed layer are compatible with ALD and at least some of the conductive materials that are compatible do not provide strong adhesion with the metal to be subsequently electroplated thereto. Accordingly, in some examples, an inserter or transition layer is deposited onto the metal seed layer deposited using ALD to promote greater adhesion for the product of reliable high aspect ratio vias.

Further examples and combinations thereof include the following:

Example 1 includes a package substrate comprising a core having a via extending therethrough, a first conductive material in the via, a dielectric material at least partially between a wall of the via and the first conductive material, and a second conductive material in the via, the second conductive material closer to a central region of the via than the first conductive material is to the central region of the via, the first conductive material different from the second conductive material, the first conductive material at least partially between the dielectric material and the second conductive material.

Example 2 includes the package substrate of example 1, wherein the core is a glass core.

Example 3 includes the package substrate of any one of examples 1 or 2, wherein the first conductive material includes ruthenium, and the second conductive material includes copper.

Example 4 includes the package substrate of example 3, wherein the first conductive material includes both ruthenium and copper.

Example 5 includes the package substrate of any one of examples 1-4, wherein the via has an aspect ratio of at least 6.

Example 6 includes the package substrate of example 5, wherein the first conductive material has a first thickness at a first end of the via, a second thickness at a second end of the via, and a third thickness at a midpoint of the via, the first thickness approximately equal to the second thickness and approximately equal to the third thickness.

Example 7 includes the package substrate of any one of examples 1-6, wherein the dielectric material has a thickness between approximately 0.5 micrometers and 9 micrometers.

Example 8 includes the package substrate of any one of examples 1-7, wherein the first conductive material has a thickness less than 70 nanometers.

Example 9 includes the package substrate of any one of examples 1-8, further including a third conductive material at least partially between the first conductive material and the second conductive material, the third conductive material different from the first conductive material and different from the second conductive material.

Example 10 includes the package substrate of example 9, wherein the third conductive material has a thickness between approximately 5 nanometers and 100 nanometers.

Example 11 includes the package substrate of any one of examples 9 or 10, wherein the third conductive material includes at least one of titanium or copper.

Example 12 includes a package substrate comprising a glass core having a through-hole extending from a first surface of the glass core to a second surface of the glass core, a dielectric liner covering an inner surface of the through-hole, a conductive liner covering the dielectric liner, and a conductive fill material within the through-hole, the conductive liner including a different composition from the conductive fill material, the conductive liner separating the dielectric liner from the conductive fill material.

Example 13 includes the package substrate of example 12, wherein the conductive liner includes ruthenium.

Example 14 includes the package substrate of any one of examples 12 or 13, wherein a length of the through-hole is at least 10 times a width of the through-hole, the conductive liner conformally coating the dielectric liner with a substantially consistent thickness along the length of the through-hole.

Example 15 includes the package substrate of any one of examples 12-14, wherein the conductive liner includes less than 0.1wt % of titanium.

Example 16 includes the package substrate of any one of examples 12-15, wherein the dielectric liner includes an inorganic filler.

Example 17 includes the package substrate of any one of examples 12-16, wherein the dielectric liner includes at least one of an epoxy, a polyimide, or a parylene.

Example 18 includes the package substrate of any one of examples 12-17, wherein the dielectric liner includes silicon and at least one of oxygen, nitrogen, hydrogen, or carbon.

Example 19 includes a system comprising a semiconductor die, a package substrate including a glass core, the glass core having an opening with a height to width aspect ratio of at least 9, a first conductive material within the opening, and a second conductive material between the first conductive material and sidewalls of the opening, the second conductive material having a thickness that differs by less than 5% between any two points on the sidewalls of the opening, the second conductive material including ruthenium.

Example 20 includes the system of example 19, further including at least one of a keyboard or a display.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

What is claimed is:

1. A package substrate comprising:
a core having a via extending therethrough;
a first conductive material in the via;
a dielectric material at least partially between a wall of the via and the first conductive material; and
a second conductive material in the via, the second conductive material closer to a central region of the via than the first conductive material is to the central region of the via, the first conductive material different from the second conductive material, the first conductive material at least partially between the dielectric material and the second conductive material.

2. The package substrate of claim 1, wherein the core is a glass core.

3. The package substrate of claim 1, wherein the first conductive material includes ruthenium, and the second conductive material includes copper.

4. The package substrate of claim 3, wherein the first conductive material includes both ruthenium and copper.

5. The package substrate of claim 1, wherein the via has an aspect ratio of at least 6.

6. The package substrate of claim 5, wherein the first conductive material has a first thickness at a first end of the via, a second thickness at a second end of the via, and a third thickness at a midpoint of the via, the first thickness approximately equal to the second thickness and approximately equal to the third thickness.

7. The package substrate of claim 1, wherein the dielectric material has a thickness between approximately 0.5 micrometers and 9 micrometers.

8. The package substrate of claim 1, wherein the first conductive material has a thickness less than 70 nanometers.

9. The package substrate of claim 1, further including a third conductive material at least partially between the first conductive material and the second conductive material, the third conductive material different from the first conductive material and different from the second conductive material.

10. The package substrate of claim 9, wherein the third conductive material has a thickness between approximately 5 nanometers and 100 nanometers.

11. The package substrate of claim 9, wherein the third conductive material includes at least one of titanium or copper.

12. A package substrate comprising:
a glass core having a through-hole extending from a first surface of the glass core to a second surface of the glass core;
a dielectric liner covering an inner surface of the through-hole;
a conductive liner covering the dielectric liner; and
a conductive fill material within the through-hole, the conductive liner including a different composition from the conductive fill material, the conductive liner separating the dielectric liner from the conductive fill material.

13. The package substrate of claim 12, wherein the conductive liner includes ruthenium.

14. The package substrate of claim 12, wherein a length of the through-hole is at least 10 times a width of the through-hole, the conductive liner conformally coating the dielectric liner with a substantially consistent thickness along the length of the through-hole.

15. The package substrate of claim 12, wherein the conductive liner includes less than 0.1 wt % of titanium.

16. The package substrate of claim 12, wherein the dielectric liner includes an inorganic filler.

17. The package substrate of claim 12, wherein the dielectric liner includes at least one of an epoxy, a polyimide, or a parylene.

18. The package substrate of claim 12, wherein the dielectric liner includes silicon and at least one of oxygen, nitrogen, hydrogen, or carbon.

19. A system comprising:
a semiconductor die;
a package substrate including a glass core, the glass core having an opening with a height to width aspect ratio of at least 9;
a first conductive material within the opening; and
a second conductive material between the first conductive material and sidewalls of the opening, the second conductive material having a thickness that differs by less than 5% between any two points on the sidewalls of the opening, the second conductive material including ruthenium.

20. The system of claim 19, further including at least one of a keyboard or a display.
